(19) United States
(12) Patent Application Publication
(10) Pub. No.: US 2006/0176107 A1
(43) Pub. Date: Aug. 10, 2006

(54) Amplifier, voltage stabilizing unit and method thereof

(76) Inventor: Sung-hoon Kim, Seongnam-si (KR)

Correspondence Address: HARNESS, DICKEY & PIERCE, P.L.C., P.O. BOX 8910, RESTON, VA, 20195, US

(21) Appl. No.: 11/341,043

(22) Filed: Nov. 17, 2005

(30) Foreign Application Priority Data
Feb. 5, 2005 (KR) 10-2005-0011009

(51) Int. Cl. H03F 1/00

(52) U.S. Cl. 330/1 R

(57) ABSTRACT

An amplifier, a voltage stabilizing unit and a method thereof. In the method, a determination may be made as to whether there is a current fluctuation in a signal, for example where the signal is a current output by at least one input unit. If the current fluctuation is detected, for example due to a transistor turning off, the current fluctuation in the signal may be compensated for by outputting at least one current. An output voltage based on the compensated signal may be maintained at a stable level irrespective of the current fluctuation due to the compensation. The method may be performed by an amplifier and/or a voltage stabilizing unit. The voltage stabilizing unit may be included in the amplifier.

### PRIORITY STATEMENT

This application claims the benefit of Korean Patent Application No. 10-2005-0011009, filed on Feb. 5, 2005, in the Korean Intellectual Property Office, the disclosure of which is incorporated herein in its entirety by reference.

### BACKGROUND OF THE INVENTION

1. Field of the Invention

Example embodiments of the present invention relate to an amplifier, a voltage stabilizing unit and a method thereof, and more particularly to an amplifier and a voltage stabilizing unit for maintaining a stable voltage and method thereof.

2. Description of the Related Art

Semiconductor devices (e.g., mobile communication devices) may employ lower-voltage technologies. However, lower voltages may cause a narrowing of a swing width of an input signal received at a semiconductor device. The swing width of the input signal may thereby be extended to compensate for the narrowing.

In an example, a rail-to-rail amplifier may be used to extend the swing width of an input signal. In conventional rail-to-rail amplifiers, a common mode voltage level of an input signal may be set to a voltage level between a ground voltage and a power supply voltage of the input terminal. In conventional amplifiers, the input signal may be received by either a pair of NMOS transistors or a pair of PMOS transistors. In conventional rail-to-rail amplifiers, both of a pair of NMOS transistors and PMOS transistors may each receive the input signal.

FIG. 1 is a circuit diagram illustrating an input terminal 100 of a conventional rail-to-rail amplifier. Referring to FIG. 1, the input terminal 100 may detect input voltage signals VINP and VINN, may convert the detected voltage signals VINP and VINN into currents In1, In2, Ip1, and Ip2, and may output the converted currents to a gain stage 120.

Referring to FIG. 1, the input voltage signals VINP and VINN may be received at NMOS transistors N1 and N2, respectively, and PMOS transistors P1 and P2, respectively. The outputs of the transistors N1, N2, P1 and P2 may be converted into the currents In1, In2, Ip1, and Ip2, respectively. The gain stage 120 may receive the currents In1, In2, Ip1 and Ip2 to perform amplification.

Referring to FIG. 1, the transistors N1, N2, P1, and P2 may operate in a triode region or a saturation region based on a voltage level of an input signal (e.g., input signal VINN, input signal VINP, etc.). A change to an operation region may vary a transconductance gm of one or more of the input transistors N1, N2, P1 and P2.

FIG. 2 is a graph illustrating conventional transconductance variations based on an operation region of an NMOS transistor and a PMOS transistor. Referring to FIG. 2, a dotted line may indicate a transconductance of the NMOS transistor and a solid line may indicate a transconductance of the PMOS transistor with respect to a common mode input voltage Vin, cm,

As shown in FIG. 2, the NMOS transistor may operate (e.g., be turned on) in regions II and II and may not operate (e.g., be turned off) in region I. The PMOS transistor may operate (e.g., be turned on) in regions I and II and may not operate (e.g., be turned off) in region III. As shown, the transconductance of the input terminal of the rail-to-rail amplifier may vary based on the common mode input voltage Vin, cm.

A stable transconductance (e.g., a substantially constant transconductance) of the input terminal may be maintained by maintaining a substantially constant current flowing from sources of the NMOS transistors N1 and N2 and a substantially constant current Ip flowing from sources of the PMOS transistors P1 and P2.

However, it may be difficult to maintain the currents In1 and In2 flowing from the gain stage to drains of the NMOS transistors N1 and N2 and/or the currents Ip1 and Ip2 flowing from drains of the PMOS transistors P1 and P2 to the gain stage at stable or substantially constant levels. Further, a voltage level of a common mode output voltage Vout, cm output from the gain stage may not correspond to that of the common mode input voltage Vin, cm.

FIG. 3A is a graph illustrating a transconductance characteristic of an input terminal of a conventional rail-to-rail amplifier. Referring to FIG. 3A, a transconductance gmn of an NMOS transistor and a transconductance gmp of a PMOS transistor may be turned off based on a change in an input voltage Vin, cm. The transconductance of the input terminal of the conventional rail-to-rail amplifier may be equal to a sun of the transconductances gmn and gmp of the NMOS transistor and the PMOS transistor, respectively, and may thereby not be stable (e.g., constant) with respect to changes of the common mode input voltage Vin, cm.

FIG. 3B is a graph illustrating a voltage characteristic of a common mode input voltage of the conventional rail-to-rail amplifier. Referring to FIG. 3B, a voltage level of the common mode output voltage Vout, cm of the rail-to-rail amplifier may vary based on a change in the common mode input voltage Vout, cm, for example due to a mismatching of currents flowing from transistors (e.g., N1, N2, P1 and/or P2) to the gain stage 120,

### SUMMARY OF THE INVENTION

An example embodiment of the present invention is directed to an amplifier, including at least one input unit receiving a first input signal and a second input signal and outputting an output signal related to a voltage difference between the first input signal and the second input signal, at least one controller monitoring the output signal, a current compensator adjusting the output signal if the at least one controller detects a fluctuation in the output signal, the adjustment maintaining the output signal at a stable level and an amplifying unit amplifying the adjusted output signal.

Another example embodiment of the present invention is directed to a voltage stabilizing unit, including at least one controller detecting a current fluctuation by monitoring a difference in the voltage levels of first and second input signals, the at least one controller outputting at least one control signal indicating that the detected current has changed and a current compensation input unit compensating for the current fluctuation in response to the at least one control signal by outputting at least one current so as to stabilize the detected current.

Another example embodiment of the present invention is directed to a method of stabilizing a voltage, including determining whether there is a current fluctuation in a signal, compensating for the current fluctuation by outputting at least one current and outputting an output voltage based on the signal, the output voltage maintained at a stable voltage level irrespective of whether the current fluctuation occurs in the signal.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a circuit diagram illustrating an input terminal of a conventional rail-to-rail amplifier.

FIG. 2 is a graph illustrating conventional transconductance variations based on an operation region of an NMOS transistor and a PMOS transistor.

FIG. 3A is a graph illustrating a transconductance characteristic of an input terminal of the conventional rail-to-rail amplifier of FIG. 1.

FIG. 3B is a graph illustrating a voltage characteristic of a common mode input voltage of the conventional rail-to-rail amplifier of FIG. 1.

FIG. 4 is a circuit diagram illustrating a rail-to-rail amplifier according to an example embodiment of the present invention.

FIG. 5 illustrates a current compensation in the rail-to-rail amplifier of FIG. 4 according to another example embodiment of the present invention.

FIGS. 6A and 6C are circuit diagrams of first sub controllers according to another example embodiment of the present invention.

FIGS. 6B and 6D are circuit diagrams of second sub controllers according to another example embodiment of the present invention.

FIG. 6E is a graph illustrating voltage levels of output signals of first and second controllers according to another example embodiment of the present invention.

FIG. 7A is a graph illustrating a comparison of transconductances of a conventional rail-to-rail amplifier with the rail-to-rail amplifier of FIG. 4 according to another example embodiment of the present invention.

FIG. 7B illustrate graphs comparing common mode output voltages of a conventional rail-to-rail amplifier with the rail-to-rail amplifier of FIG. 4 according to another example embodiment of the present invention.

FIG. 7C is a graph illustrating a comparison of direct current (DC) levels of common mode output voltages of a conventional amplifier and with the rail-to-rail amplifier of FIG. 4 according to another example embodiment of the present invention.

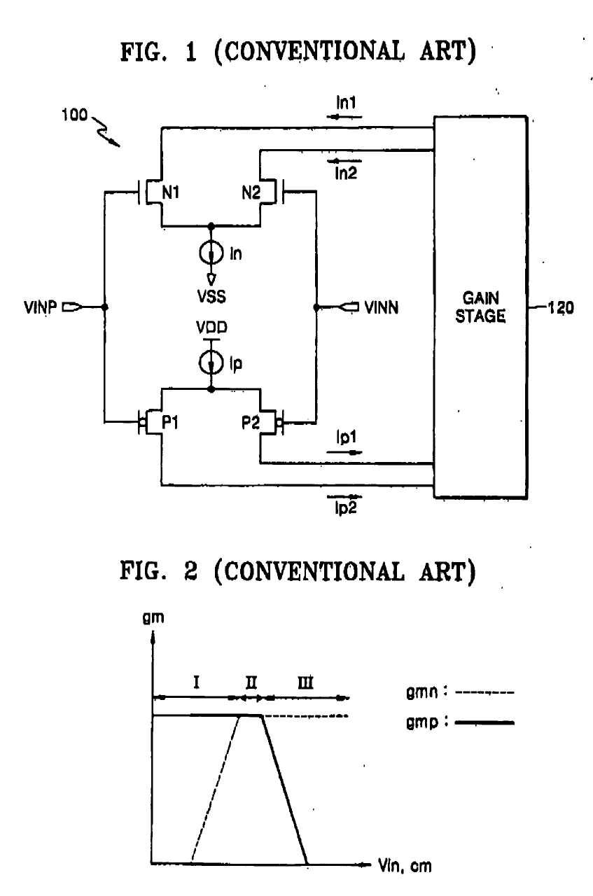

### DETAILED DESCRIPTION OF EXAMPLE EMBODIMENTS OF THE PRESENT INVENTION

Hereinafter, example embodiments of the present invention will be described in detail with reference to the accompanying drawings.

In the Figures, the same reference numerals are used to denote the same elements throughout the drawings,

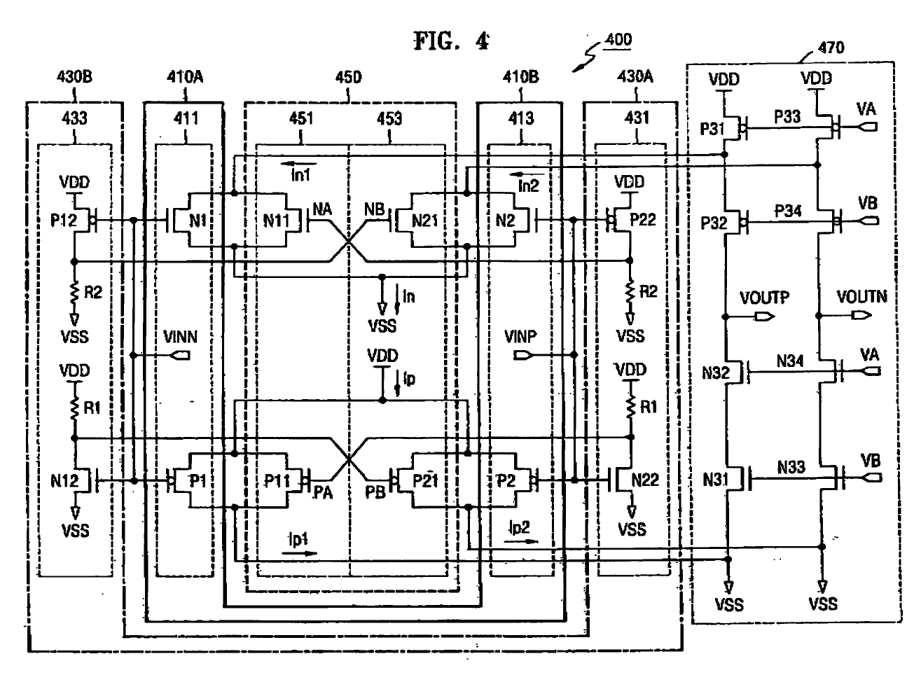

FIG. 4 is a circuit diagram illustrating a rail-to-rail amplifier 400 according to an example embodiment of the present invention.

In the example embodiment of FIG. 4, the rail-to-rail amplifier 400 may include first and second input units 410A and 410B, respectively, an amplifying unit 470, first and second controllers 430A and 430B, and a current compensator 450. The first and second input units 410 A/B may convert a voltage difference between a first input signal and a second input signal into a current and may output the converted current. The amplifying unit 470 may amplify the converted current received from the input units 410 A/B and may output the amplified current. The amplifying unit 470 may be configured as any well-known amplifier, % and as such its structure and operation will not be described in further detail for the sake of brevity.

In the example embodiment of FIG. 4, the first input unit 410A may include a first sub input unit 411 and the second input unit 410B may include a second sub input unit 413. The first sub input unit 411 may output a first current to the amplifying unit 470 in response to a first input signal VINN. The second sub input unit 413 may output a second current to the amplifying unit 470 in response to a second input signal VINP.

In the example embodiment of FIG. 4, the first sub input unit 411 of the first input unit 410A may include a first input transistor N1 and a second input transistor P1. The second sub input unit 413 may include a third input transistor N2 and a fourth input transistor P2. The first input transistor N1 may have a source connected to a ground voltage VSS and a drain connected to the amplifying unit 470. The first input transistor N1 may output the N first current to the amplifying unit 470 in response to the first input signal VINN received at a gate of the first input transistor N1. The second input transistor P1 may have a source connected to a power voltage VDD and a drain connected to the amplifying unit 470. The second input transistor P1 may output the second current to the amplifying unit 470 in response to the first input signal VINN received at a gate of the second input transistor P1.

In the example embodiment of FIG. 4, the second sub unit 413 of the second input unit 410B may include a third transistor N2 and a fourth transistor P2. The third input transistor N2 may have a source connected to the ground voltage VSS and a drain connected to the amplifying unit 470. The third input transistor N2 may output the first current to the amplifying unit 470 in response to the second input signal VINP received at a gate of the third input transistor N2. The fourth input transistor P2 may have a source connected to the power voltage VDD and a drain connected to the amplifying unit 470. The fourth input transistor P2 may output the first current to the amplifying unit 470 in response to the second

In the example embodiment of FIG. 4, the first and second controllers 430 A/B may sense a difference between currents generated in the first and second input units 410 A/B and may control an operation of the current compensator 450. For example, if the input transistors N1, N2, P1, and P2 are turned off and thereby output reduced currents, the first and second controllers 430 A/B may control the current compensator 450 so as to compensate for (e.g., increase) the reduced current levels.

In the example embodiment of FIG. 4, the first controller 430A may include a first sub controller 431 and the second controller 430B may include a second sub controller 433. The first sub controller 431 may control a first sub current compensator 451 of the current compensator 450 to compensate for a current difference at the first sub input unit 411 in response to the second input signal VINP. The second sub controller 433 may control the second current compensator 453 to compensate for a current difference at the second sub input unit 413 in response to the first input signal VINN. The first sub controller 431 may include a first transistor P22 and a second control transistor N22. The second hub controller 433 may include a third control transistor P12 and a fourth control transistor N12.

In the example embodiment of FIG. 4, the first control transistor P22 may have a source connected to the power voltage VDD and a drain connected to the ground voltage VSS through a first resistance R2. The first control transistor P22 may control a first compensation transistor N11 to compensate for a current change or fluctuation when the first input transistor N1 is turned off in response to the second input signal VINP. For example, the first control transistor P22 may compensate for reduced current levels when the first input transistor N1 is turned off by turning on the first compensation transistor N11.

In the example embodiment of FIG. 4, the second control transistor N22 may have a drain connected to the power voltage VDD through a second resistance R1 and a source connected to the ground voltage VSS. The second control transistor N22 may control a second compensation transistor P11 to compensate for a current change or fluctuation when the second input transistor P1 is turned off in response to the second input signal VINP. For example, the second control transistor N22 may compensate for (e.g., increase) reduced current levels when the second input transistor P1 is turned off by turning on the second compensation transistor P11.

In the example embodiment of FIG. 4, the third control transistor P12 may have a source connected to the power voltage VDD and a drain connected to the ground voltage VSS through the first resistance R2. The third control transistor may control a third compensation transistor N21 to compensate for a current change when the third input transistor N2 is turned off in response to the first input signal VINN. For example, the third control transistor P12 may compensate for (e.g., increase) reduced current levels when the third input transistor N2 is turned off by turning on the third compensation transistor N21.

in the example embodiment of FIG. 4, the fourth control transistor N12 may have a drain connected to the power voltage VDD through the second resistance R1 and a source connected to the ground voltage VSS. The fourth control transistor N12 may control a fourth compensation transistor P21 to compensate for a current change or fluctuation when the fourth input transistor P2 is turned off in response to the first input signal VINN. For example, the fourth control transistor N12 may compensate for (e.g., increase) reduced current levels when the fourth input transistor P2 is turned off by turning on the fourth compensation transistor P21.

In the example embodiment of FIG. 4, the current compensator 450 may compensate for a current change in the input units 410 based on a voltage change of the first input signal VINN and the second input signal VINP. The current compensator 450 may include the first sub current compensator 451 and the second sub current compensator 453. The first sub current compensator 451 may compensate for a current change or fluctuation in the first sub input unit 411 in response to outputs NA and PA of the first sub controller 431. The second sub current compensator 453 may compensate for a current change in the second sub input unit 413 in response to outputs NB and PB of the second sub controller 433.

In the example embodiment of FIG. 4, the first sub current compensator 451 may include the first compensation transistor N11 and the second compensation transistor P11. The second sub current compensator 453 may include the third compensation transistor N21 and the fourth compensation transistor P21.

In the example embodiment of FIG. 4, the first compensation transistor N11 may be connected in parallel with the first input transistor N1. In an example, the first compensation transistor N11 may compensate for a current change when the first input transistor N1 is turned off in response to the output NA of the first control transistor P22 received at a gate of the first compensation transistor N11.

In the example embodiment of FIG. 4, the second compensation transistor P11 may be connected in parallel with the second input transistor P1. In an example, the second compensation transistor P11 may compensate for a current change when the second input transistor P1 is turned off in response to the output PA of the second control transistor N22 received at a gate of the second compensation transistor P11.

In the example embodiment of FIG. 4, the third compensation transistor N21 may be connected in parallel with the third input transistor N2. In an example, the third compensation transistor N21 may compensate for a current change when the third input transistor N2 is turned off in response to the output NB of the third control transistor P12 received at a gate of the third compensation transistor N21.

In the example embodiment of FIG. 4, the fourth compensation transistor P21 may be connected in parallel with the fourth input transistor P2. In an example, the fourth compensation transistor P21 may compensate for a current change when the fourth input transistor P2 is turned off in response to the output PB of the fourth control transistor N12 received at a gate of the fourth compensation transistor P21.

In the example embodiment of FIG. 4, the first and third input transistors N1 and N2, the second and fourth control transistors N12 and N22 and the fist and third compensation transistors N11 and N21 may be NMOS transistors. The second and fourth input transistors P1 and P2, the first and third control transistors P12 and P22, and the second and fourth compensation transistors P11 and P21 may be PMOS transistors. However, it is understood that other example embodiments may be configured with other combinations of transistor types.

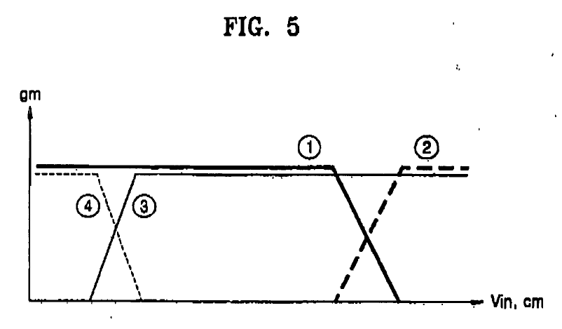

FIG. 5 illustrates a current compensation in the rail-to-rail amplifier 400 of FIG. 4 according to another example embodiment of the present invention.

In the example embodiment of FIG. 5, a transconductance of a PMOS transistor may be denoted by thick solid line \textcircled{1}, a transconductance of a first compensation transistor compensating for the transconductance of the PMOS transistor may be denoted by thick dotted line \textcircled{2}, a transconductance of a NMOS transistor may be denoted by thin solid line \textcircled{3} and a transconductance of a second compensation transistor compensating for the transconductance of the NMOS transistor may be denoted by thin dotted line \textcircled{4}.

In the example embodiment of FIG. 5, the PMOS transistor (e.g., represented as thick solid line \textcircled{1}) may be turned off for a given period of time as a common mode input voltage rises above a given threshold. The first compensation transistor (e.g., represented as thick dotted line \textcircled{2}) may be turned on while the PMOS transistor is turned off so as to maintain a stable (e.g., constant) transconductance. Thus, when the PMOS transistor is turned off the current through the PMOS transistor is reduced. The PMOS transistor may be connected in parallel with the first compensation transistor such that the reduced current levels at the PMOS transistor may be maintained by turning on the first compensation transistor. The above-described parallel connection may allow a stable current to be maintained irrespective of whether the PMOS transistor turns off.

Similarly, the NMOS transistor (e.g., represented as thin solid line \textcircled{3}) may be connected in parallel with the second compensation transistor (e.g., represented as thin dotted line \textcircled{4}) such that the second compensation transistor may be turned on if the NMOS transistor is turned off, thereby stabilizing an output current of voltage irrespective of whether the NMOS transistor is turned off.

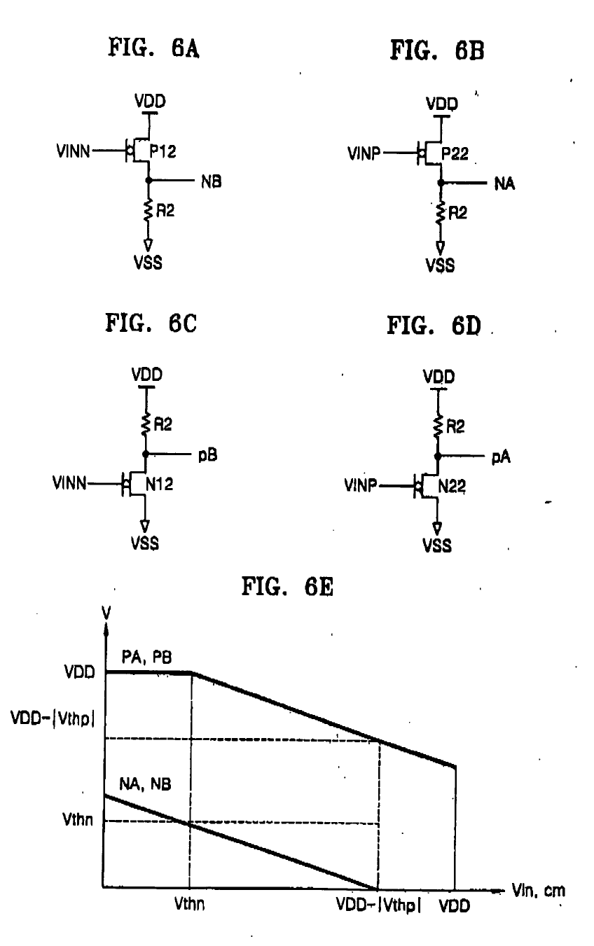

FIGS. 6A and 6C are circuit diagrams of portions of the second controller 430B of FIG. 4 according to another example embodiment of the present invention.

FIGS. 6B and 6D are circuit diagrams of portions of the first controller 430A of FIG. 4 according to another example embodiment of the present invention.

FIG. 6B is a graph illustrating voltage levels of output signals of the first and second controllers 430 A/B according to another example embodiment of the present invention.

In the example embodiment of FIGS. 4-6E, the rail-to-rail amplifier 400 may operate in a common mode where a voltage level of the first input signal Vow may be related (e.g., equal) to the second input signal VINP. The first and second input voltages VINN and VINP of the rail-to-rail amplifier 400 may vary between a ground voltage VSS and a power voltage VDD.

In the example embodiment of FIGS. 46E, if the common mode input voltage Vin, cm is higher tan the ground voltage VSS and lower than a turn-on threshold voltage Vthn of an NMOS transistor (e.g., first input transistor N11, third input transistor N21, etc.), the second and fourth input transistors P1 and P2 may be turned on and the first and third input transistors N1 and N2 may be turned off. Current levels at the first and second input units 410 A/B may thereby be reduced. If the first and third control transistors P1 and P22 sense a turn-off of the first and third input transistors N1 and N2, the first and third compensation transistors N11 and N21 may compensate for the reduced currents of the input units 410. Referring to FIGS. 6A and 6B, current Idp may flow in the first and third control transistors P12 and P22 when the common mode input voltage Vin, cn is lower than a value represented by VDD-|Vthp|, where Vthp may be a turn-on threshold voltage of a PMOS transistor (e.g., first control transistor P12, third control transistor P22, etc.).

In the example embodiment of FIGS. 4-6E, signals NA and NB may be received at gates of the first and third compensation transistors N11 and N21, respectively. The received signals NA and NB may approximate (e.g., be equal) to voltages of drains of the first and third control transistors P12 and P22, respectively. A voltage level of the signals NA and NB may be adjusted by the resistance R2. The signals NA and NB may have a voltage represented by the expression VDD-Idp×R2, as illustrated in FIG. GE.

In the example embodiments of FIGS. 6A, 6B, and 6E, if the common mode input voltage Vin, cm is higher than the ground voltage VSS and lower than the turn-on threshold voltage Vthn of an NMOS transistor (e.g., first input transistor N11, third input transistor N21, etc.), drains of the first and third control transistors P12 and P22 may have a voltage level higher than the turn-on threshold voltage Vthn of the NMOS transistor. The first and third compensation transistors N11 and N21 may be turned on in response to the signals NA and NB so as to compensate for the reduced current levels when the first and third input transistors N1 and N2 are turned off.

In the example embodiments of FIGS. 6A, 6B, and 6E, if the common mode input voltage Vin, cm is lower than the power voltage VDD and higher than the voltage represented by VDD-|Vthp|, the first and third input transistors N1 and N2 may be turned on and the second and fourth input transistors P1 and P2 may be turned off, thereby reducing current levels at the first and second input units 410 A/B. If the second and fourth control transistors N12 and N22 sense a turn-off of the second and fourth input transistors P1 and P2, the second and fourth compensation transistors P11 and P21 may compensate for the reduced current levels at the first and second input units 410 A/B.

In the example embodiment of FIGS. 6C and 6D, current Idn may flow in the second and fourth control transistors N12 and N22 when the common mode input voltage Vin, cm is higher than the turn-on threshold voltage Vthn. Signals PA and PB may be received at gates of the second and fourth compensation transistors P11 and P21, respectively. The received signals PA and PB may approximate (e.g., be equal to) voltages of drains of the second and fourth control transistors N12 and N22, respectively. A voltage level of the signals PA and PB may be adjusted by the resistance R1. The signals PA and PB may have a voltage represented by VDD-Idn×R1, as illustrated in FIG. 6E.

In the example embodiment of FIGS. 6A, 6B, and 6E, if the common mode input voltage Vin, cm is lower than the power voltage VDD and higher than a voltage represented by VDD-|Vthp|, drains of the second and fourth control transistors N12 and N22 may have a voltage lower than the expression VDD-|Vthp|. The second and fourth compensation transistors P11 and P21 may be turned on in response to the signals PA and PB having a voltage level lower than the expression VDD-|Vthp| so as to compensate for reduced current levels when the second and fourth input transistors P1 and P2 are turned off. If the common mode input voltage Vin, cm is higher than the turn-on threshold voltage Vthn (e.g., of the NMOS transistor) and lower than the expression VDD-|Vthp|, each of the first through fourth input transistors N1, N2, P1, and P2 may be turned on.

In the example embodiment of FIG. 6E, if gate voltages of the first and third compensation transistors N11 and N21 (e.g., signals NA and ND, respectively) are lower than the turn-on threshold voltage Vthn and gate voltages of the second and fourth compensation transistors P11 and P21 (e.g., signals PA and PB, respectively) are higher than the expression VDD-|Vthp|, the first through fourth compensation transistors N11, N21, P11, and P21 may be turned off.

In the example embodiment of FIG. 6E, if the common mode input voltage Vin, cm is higher than the turn-on threshold voltage Vthn (e.g., of an NMOS transistor) and lower than the expression VDD-|Vthp|, a current level at the first and second input units 410 A/3 may not be changed Thus, a current compensation need not be performed and the first through fourth transistors N11, N21, P11, and P21 of the current compensator 450 may be turned off

In another example embodiment of the present invention, the first and second input units 410 A/B and the current compensator 450 may compensate for an internal current fluctuation by detecting a change in voltage levels of the first input signal VINN and the second input signal VINP. The first and second input units 410 A/B and the current compensator 450 may convert the detected voltage difference of the first input signal VINN and the second input signal VINP into a corresponding current and may output the converted current so as to maintain a stable internal current. The first and second controllers 430 A/B may sense a change in an internal current and may control an operation of the first and second input units 410 A/B and the current compensator 450 to return or maintain the internal current to a stable (e.g., constant) level.

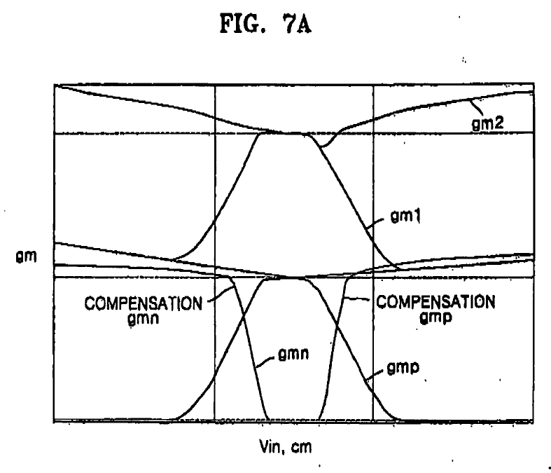

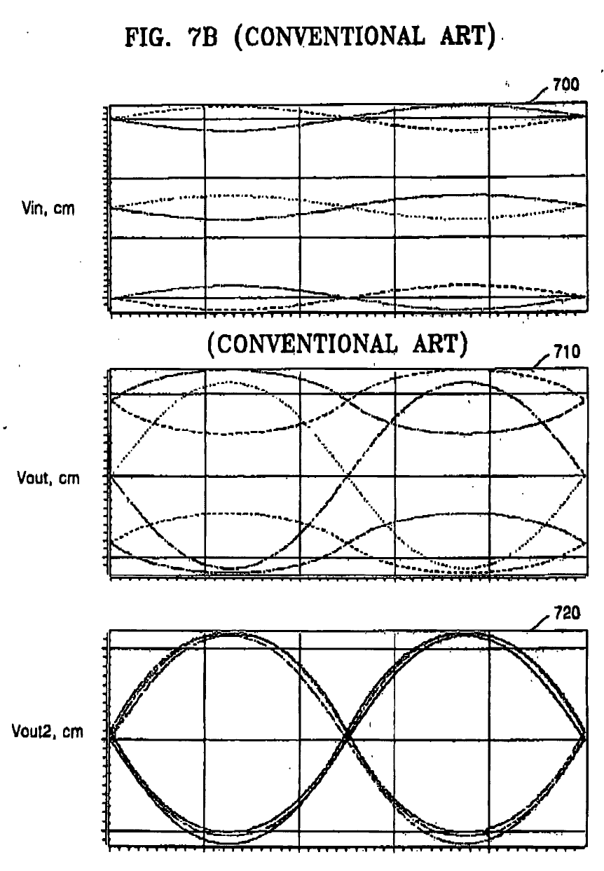

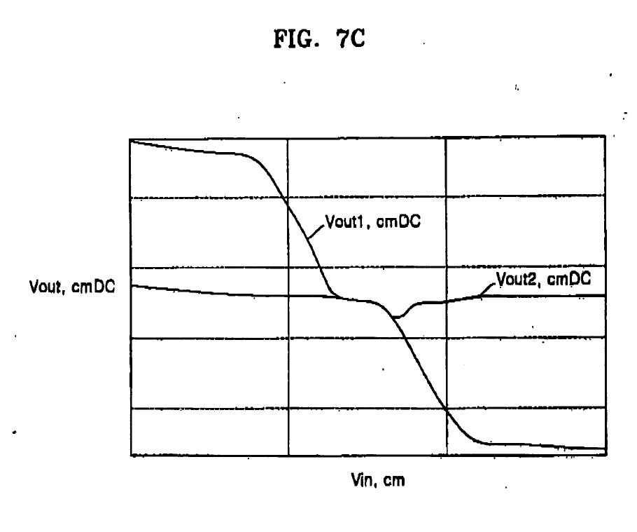

FIG. 7A is a graph illustrating a comparison of transconductances of a conventional rail-to-rail amplifier with the rail-to-rail amplifier 400 of FIG. 4 according to another embodiment of the present invention. In the example embodiment of FIG. 7A, gmn may denote a transconductance of the input transistors N1 and N2, gmp may denote a transconductance of the input transistors P1 and P2, COMPENSATION gmn may denote a transconductance of the compensation transistors N11 and N21 and COMPENSATION gmp may denote transconductance of the compensation transistors P11 and P21.

In the example embodiment of FIG. 7A, gm1 may denote a transconductance of an input unit of the conventional amplifier and may approximate a value obtained by adding the transconductance gmn of the input transistors N1 and N2 and the transconductance gmp of the input transistors P1 and P2. The transconductance gm1 of the conventional amplifier may have a convex shape, as shown in FIG. 7A, and may thereby not be stable (e.g., constant).

In the example embodiment of FIG. 7A, gm2 may denote a transconductance obtained by adding the transconductance gmn of the input transistors N1 and N2, the transconductance gmp of the input transistors P1 and P2 and the transconductances COMPENSATION gmn and COMPENSATION gmp of the compensation transistors N11, N21, P11 and P21. The transconductance gm2 may be maintained at a stable level (e.g., a constant or relatively constant level) irrespective of the common mode input voltage Vin, cm.

FIG. 7B illustrate graphs 700/710/720 comparing common mode output voltages of a conventional rail-to-rail amplifier with the rail-to-rail amplifier of FIG. 4 according to another example embodiment of the present invention. In the example embodiment of FIG. 7B, the graph 700 illustrates a common mode input voltage, the graph 710 illustrates a common mode output voltage of the conventional amplifier and the graph 720 illustrates a common mode output voltage of an amplifier according to another embodiment of the present invention.

In the example embodiment of FIG. 7B, referring to the graph 700, three voltage curves of the common mode input voltage Vin, cm may be used to simulate an output of an amplifier (e.g., see either of graphs 710 or 720).

In the example embodiment of FIG. 7B, referring to the graph 710, a gain and a voltage curve representing the common mode output voltage may vary substantially based on a change in transconductance.

In the example embodiment of FIG. 7B, referring to the graph 720, a gain and a voltage curve representing the common mode output voltage may remain stable (e.g., relatively constant) irrespective of fluctuations in transconductance (e.g., because the transconductance may be compensated for).

FIG. 7C is a graph illustrating a comparison of direct current (DC) levels of common mode output voltages of a conventional amplifier with the rail-to-rail amplifier 400 of FIG. 4 according to another example embodiment of the present invention,

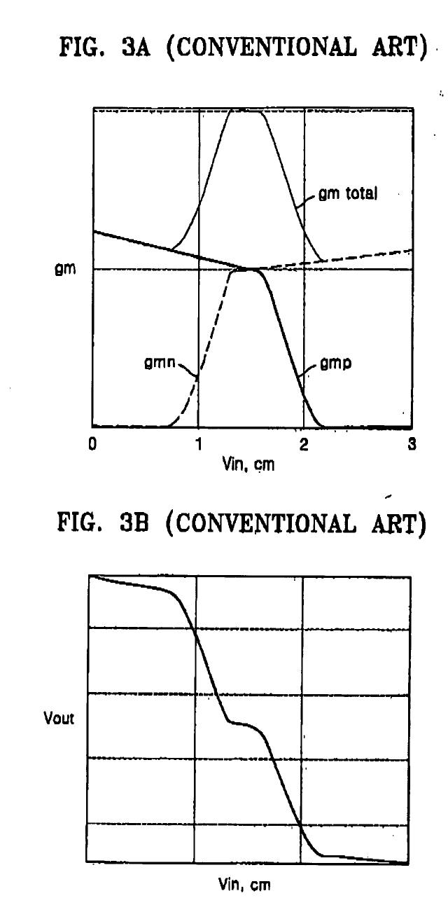

In the example embodiment of FIG. 7C, the common mode output voltage Vout, cm of the amplifier (e.g., rail-to-rail amplifier 400 of FIG. 4) may have a more stable (e.g., relatively constant) DC level throughout the entire region of the common mode input voltage Vin, cm as compared to the common mode output voltage Vout1, cm of the conventional amplifier (e.g., also shown in conventional FIG. 3B).

In another example embodiment of the present invention, a rail-to-rail amplifier (e.g., rail-to-rail amplifier 400 of FIG. 4) may a current fluctuation (e.g., by sensing a transistor of an input terminal turning off). The rail-to-rail amplifier may compensate for the detected current fluctuation induced by the transistor turning off so as to maintain a stable (e.g., relatively constant) transconductance at the input terminal. A stable (e.g., relatively constant) current may thereby flow to the gain stage from the input terminal. The stable current flowing to the gain stage may allow the rail-to-rail amplifier to maintain a stable (e.g. relatively constant) common mode output voltage.

Example embodiments of the present invention being thus described, it will be obvious that the same may be varied in many ways. For example, while the common mode input voltage is described above as having three distinct voltage levels, it is understood that rail-to-rail amplifiers according to other example embodiments of the present invention may be configured for common mode input voltages having any number of levels.

Further, while above-described example embodiments of the present invention are directed to an amplifier (e.g., a rail-to-rail amplifier), it is understood that other example embodiments of the present invention may be directed to any semiconductor device benefiting from stabilizing an input voltage. For example, the above-described input units,

A controllers, and/or channel compensators may be configured to output a stable voltage in any semiconductor device.

Further, while above-described example embodiments refer to “stable” currents and/or voltages, it is understood tat stable may not necessarily be intended to mean a constant or relatively constant measure, but may rather be any voltage or current level which may have less variance, and hence be more stable, than amplifiers or other semiconductor devices not employing a compensation for current and/or voltage fluctuations (e.g., due to transistors turning off during or after a change in operating regions).

Such variations are not to be regarded as departure from the spirit and scope of example embodiments of the present invention, and all such modifications as would be obvious to one skilled in the art are intended to be included within the scope of the following claims.

What is claimed is:

1. An amplifier, comprising:
at least one input unit receiving a first input signal and a second input signal and outputting an output signal related to a voltage difference between the first input signal and the second input signal;
at least one controller monitoring the output signal;
a current compensator adjusting the output signal if the at least one controller detects a fluctuation in the output signal, the adjustment maintaining the output signal at a stable level; and
an amplifying unit amplifying the adjusted output signal.

2. The amplifier of claim 1, wherein the amplifying unit operates in a common-mode where a voltage level of the first input signal approximates a voltage level of the second input signal.

3. The amplifier of claim 1, wherein the detected fluctuation is one of an increase and a decrease detected in a current of the output signal.

4. The amplifier of claim 1, wherein the at least one input unit has a rail-to-rail structure.

5. The amplifier of claim 1, wherein the at least one input unit includes:
a first sub input unit outputting a first current to the amplifying unit in response to the first input signal; and
a second sub input unit outputting a second current to the amplifying unit in response to the second input signal.

6. The amplifier of claim 5, wherein the first sub input unit includes:
a first input transistor having a source connected to a ground voltage, a drain connected to the amplifying unit and a gate receiving the first input signal, the first input transistor outputting the first current to the amplifying unit in response to the first input signal; and
a second input transistor having a source connected to a power voltage, a drain connected to the amplifying unit and a gate received the first input signal, the second input transistor outputting the first current to the amplifying unit in response to the first input signal.

7. The amplifier of claim 5, wherein the second sub unit includes:
a first input transistor having a source connected to a ground voltage, a drain connected to the amplifying unit and a gate receiving the second input signal, the first input transistor outputting the second current to the amplifying unit in response to the second input signal; and
a second input transistor having a source connected to a power voltage, a drain connected to the amplifying unit and a gate received the second input signal, the second input transistor outputting the second current to the amplifying unit in response to the second input signal.

8. The amplifier of claim 1, wherein the at least one controller includes:
a first sub controller controlling the current compensator to compensate for a current fluctuation detected in the first sub input unit in response to the second input signal; and
a second sub controller controlling the current compensator to compensate for a current fluctuation detected in the second sub input unit in response to the first input signal.

9. The amplifier of claim 8, wherein the first sub controller includes:
a first control transistor having a source connected to a power voltage and a drain connected to a ground voltage through a first resistance, the first control transistor controlling the current compensator to compensate for a current fluctuation when a first input transistor is turned off in response to the second input signal; and
a second control transistor having a drain connected to the power voltage through a second resistance and a source connected to the ground voltage, the second control transistor controlling the current compensator to compensate for a current fluctuation when a second input transistor is turned off in response to the second input signal.

10. The amplifier of claim 8, wherein the second sub controller includes:
a first control transistor having a source connected to a power voltage and a drain connected to a ground voltage through a first resistance, the first control transistor controlling the current compensator to compensate for a current fluctuation when a first input transistor is turned off in response to the second input signal; and
a second control transistor having a drain connected to the power voltage through a second resistance and a source connected to the ground voltage, the second control transistor controlling the current compensator to compensate for a current fluctuation when a second input transistor is turned off in response to the second input signal.

11. The amplifier of claim 1, wherein the current compensator includes:
a first sub current compensator compensating for a current fluctuation in a first sub input unit of the at least one input unit in response to a first control signal received from a first sub controller of the at least one controller; and
a second sub current compensator compensating for a current fluctuation in a second sub input unit of the at least one input unit in response to a second control signal received from of a second sub controller of the at least one controller.

12. The amplifier of claim 11, wherein the first sub current compensator includes:
a first compensation transistor connected in parallel with a first input transistor, the first compensation transistor compensating for a current fluctuation occurring when the first input transistor is turned off in response to a first signal received from the at least one controller; and
a second compensation transistor connected in parallel with a second input transistor, the second compensation transistor compensating for a current fluctuation occurring when the second input transistor is turned off in response to a second signal received from the at least one controller.

13. The amplifier of claim 11, wherein the second sub current compensator includes:
a first compensation transistor connected in parallel with a first input transistor, the tint compensation transistor compensating for a current fluctuation occurring when the first input transistor is turned off in response to a first signal received from the at least one controller, and
a second compensation transistor connected in parallel with a second input transistor, the second compensation transistor compensating for a current fluctuation occurring when the second input transistor is turned off in response to a second signal received from the at least one controller.

14. The amplifier of claim 1, wherein the at least one input unit includes at least one NMOS transistor and at least one PMOS transistor.

15. A voltage stabilizing unit, comprising:
at least one controller detecting a current fluctuation by monitoring a difference in the voltage levels of first and second input signals, the at least one controller outputting at least one control signal indicating that the detected current has changed; and
a current compensation input unit compensating for the current fluctuation in response to the at least one control signal by outputting at least one current so as to stabilize the detected current.

16. The voltage stabilizing unit of claim 15, wherein the current compensation input unit has a rail-to-rail structure.

17. The voltage stabilizing unit of claim 15, wherein the current compensation input unit includes:
a first sub current compensation input unit compensating, in response to a first of the at least one control signal, for a current fluctuation in response to the first input signal by outputting a first current; and
a second sub current compensation input unit compensating, in response to a second of the at least one control signal, for a current fluctuation in response to the second input signal by outputting a second current.

18. An amplifier, including:
the voltage stabilizing unit of claim 15, compensating for the current fluctuation in the output signal;
at least one input unit receiving the first input signal and the second input signal and outputting the output signal related to a voltage difference between the first input signal and the second input signal; and
an amplifying unit amplifying the compensated output signal received from the at least one input unit.

19. A method of stabilizing a voltage, comprising:
determining whether there is a current fluctuation in a signal;
compensating for the current fluctuation by outputting at least one current; and
outputting an output voltage based on the signal, the output voltage maintained at a stable voltage level irrespective of whether the current fluctuation occurs in the signal.

20. The method of claim 19, wherein the output voltage is an amplified version of a difference between first and second input signals.

21. The method of claim 19, wherein the determining includes determining whether at least one transistor associated with the signal turns off.

22. An amplifier performing the method of claim 19.

23. A voltage stabilizing unit performing the method of claim 19.
